(19) United States
(12) Patent Application Publication
(10) Pub. No.: US 2023/0036855 A1
(43) Pub. Date: Feb. 2, 2023

(54) THIN-FILM TRANSISTOR CONTROL CIRCUITS

(71) Applicant: Obsidian Sensors, Inc., San Diego, CA (US)

(72) Inventors: Heesun SHIN, San Diego, CA (US); John HONG, San Diego, CA (US); Tallis CHANG, San Diego, CA (US); Bing WEN, San Diego, CA (US)

(73) Assignee: Obsidian Sensors, Inc., San Diego, CA (US)

(21) Appl. No.: 17/815,895

(22) Filed: Jul. 28, 2022

Related U.S. Application Data
(60) Provisional application No. 63/226,579, filed on Jul. 28, 2021.

(51) Int. Cl. H01L 27/12; H01L 27/10; B81B 7/02; H01L 27/01; H01L 27/13

(52) U.S. Cl. CPC H01L 27/1214; H01L 27/101; B81B 7/02; H01L 27/016; H01L 27/13

(57) ABSTRACT

Circuitries for controlling a power consuming device are disclosed. Methods for operating the circuitries and manufacturing the circuitries are also disclosed. In some embodiments, the circuit comprises a first thin-film transistor (TFT), a second TFT, and a storage capacitor. The first TFT is configured to output a current to a power consuming device. The second TFT is configured to provide a control voltage to the first TFT for controlling an amount of the current. The storage capacitor is configured to store the control voltage.

### CROSS-REFERENCE TO RELATED APPLICATIONS

This application claims benefit of U.S. Provisional Application No. 63/226,579, filed Jul. 28, 2021, the entire disclosure of which is herein incorporated by reference for all purposes.

### FIELD

This disclosure generally relates to circuitry for providing and controlling a current to a power consuming device.

### BACKGROUND

To control a plurality of power consuming devices, a control circuitry for controlling the power consuming devices may be required. The power consuming devices may be organized in an array. For example, the power consuming devices are anodes of an electrochemical bath, organized in an array, for electroplating. As another example, the power consuming devices are infrared emitters of an infrared scene projector organized in an array. It may be desirable to uniformly control each of the power consuming devices, such that e.g., each anode or each emitter may be controlled more accurately and consistently, independent of location. In some instances, these power consuming devices may receive a high amount of current. The current may cause location-dependent voltage drops at different device locations, causing device control to be non-uniform.

### SUMMARY

Circuitries for controlling a power consuming device are disclosed. Methods for operating the circuitries and manufacturing the circuitries are also disclosed. In some embodiments, the circuit comprises a first thin-film transistor (TFT), a second TFT, and a storage capacitor. The first TFT is configured to output a current to a power consuming device. The second TFT is configured to provide a control voltage to the first TFT for controlling an amount of the current. The storage capacitor is configured to store the control voltage.

In some embodiments, a method for operating a circuit comprises: coupling, via a second TFT of the circuit, a control voltage to a first TFT of the circuit; in response to coupling to the control voltage, outputting, via the first TFT, a current to a power consuming device, wherein the control voltage controls an amount of the current; and storing, via a storage capacitor of the circuit, the control voltage.

In some embodiments, a method for fabricating a circuit comprising: providing a power consuming device; providing a first TFT; coupling the first TFT to the power consuming device, wherein the first TFT is configured to output a current to the power consuming device; providing a second TFT; coupling the second TFT to the first TFT, wherein the second TFT is configured to couple a control voltage to the first TFT, the control voltage controlling an amount of the current; providing a storage capacitor, wherein the storage capacitor is configured to store the control voltage; and coupling the storage capacitor to the first and second TFTs.

### BRIEF DESCRIPTION OF THE DRAWINGS

FIG. 1 illustrates an exemplary circuit for controlling a power consuming device, according to embodiments of the disclosure.

FIGS. 2A-2H illustrate exemplary circuits for controlling a power consuming device, according to embodiments of the disclosure.

FIGS. 3A-3B illustrate exemplary circuits for controlling a power consuming device, according to embodiments of the disclosure.

FIGS. 4A-4C illustrate exemplary circuits for controlling a power consuming device, according to embodiments of the disclosure.

FIGS. 5A-5B illustrate exemplary structures of a circuit for controlling a power consuming device, according to embodiments of the disclosure.

FIG. 6 illustrates an exemplary structure of a circuit for controlling a power consuming device, according to embodiments of the disclosure.

FIG. 7 illustrates an exemplary structure of a circuit for controlling a power consuming device, according to embodiments of the disclosure.

FIGS. 8A-8B illustrate exemplary structures of a circuit for controlling a power consuming device, according to embodiments of the disclosure.

FIG. 9 illustrates an exemplary method for controlling a power consuming device, according to embodiments of the disclosure.

FIG. 10 illustrates an exemplary method for manufacturing a circuit for controlling a power consuming device, according to embodiments of the disclosure.

FIG. 11 illustrates a method of manufacturing an electromechanical system, according to embodiments of the disclosure.

FIG. 12 illustrates an exemplary sensor, according to embodiments of the disclosure.

### DETAILED DESCRIPTION OF EXEMPLARY EMBODIMENTS

In the following description of embodiments, reference is made to the accompanying drawings which form a part hereof, and in which it is shown by way of illustration specific embodiments which can be practiced. It is to be understood that other embodiments can be used and structural changes can be made without departing from the scope of the disclosed embodiments.

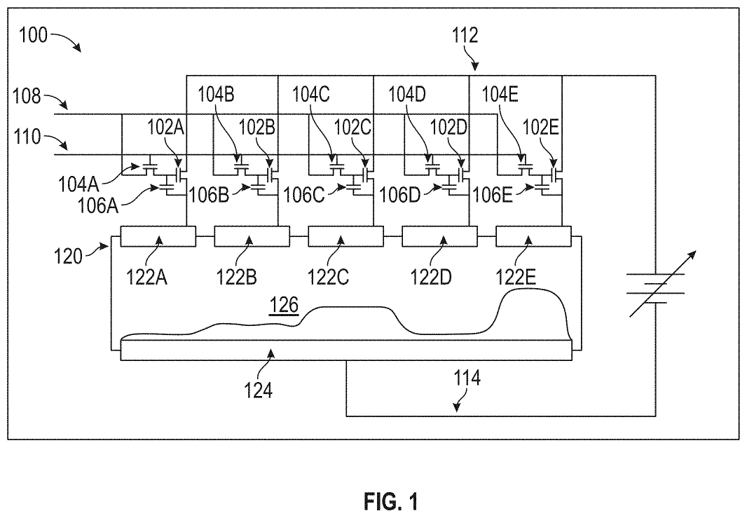

FIG. 1 illustrates an exemplary circuit 100 for controlling a power consuming device 120, according to embodiments of the disclosure. In some embodiments, the circuit 100 comprises first TFTs 102A-102E, second TFTs 104A-104E, storage capacitors 106A-106E, control voltage line 108, and row 110. In some embodiments, the first TFTs 102A-102E, second TFTs 104A-104E, storage capacitors 106A-106E, control voltage line 108, and row 110 are part of a display panel circuitry. One of the first TFTs 102A-102E, one of the second TFTs 104A-104E, and one of the storage capacitors 106A-106E coupled together may form one pixel (e.g., first TFT 102A, second TFT 104A, storage capacitor 106A form one pixel). The row 110 conducts a row control signal for turning on the second TFTs, allowing the control voltage line 108 to couple to a respective first TFT.

In some embodiments, the power consuming device 120 is an electrochemical bath for electroplating, and the electrochemical bath comprises anodes 122A-122E coupled to first TFTs 102A-102E, respectively, cathode 124, and plating solution 126. In some embodiments, a resistance between an anode and the cathode is between zero and 100 ohms. In some embodiments, the power consuming device 120 is part of circuit 100. In some embodiments, the power consuming device is not part of circuit 100.

Although FIG. 1 is described with respect to an electrochemical bath, it should be appreciated that the electrochemical bath is provided to illustrate circuitries for controlling a power consuming device. It should be appreciated that the disclosed power consuming devices can be a different kind of power consuming device (configured to receive a current provided by a disclosed circuit), such as an infrared emitting device, light emitting diodes assembled onto TFT backplanes (e.g., mini LEDs, micro LEDs for outdoor signature and display), pixelated thermionic x-ray sources, arrayed sources for active electromagnetic, acoustic, or other energetic phenomena.

As illustrated, in some embodiments, the first TFTs 102A-102E are connected to supply voltage V_{DD} 112, which, for example, is provided by a battery. The power consuming device 120 is electrically coupled to ground voltage 114.

In some embodiments, the circuit comprises a first TFT (e.g., first TFTs 102A-102E), a second TFT (e.g., second TFTs 104A-104E), and a storage capacitor (e.g., storage capacitor 106A-106E). The first TFT is configured to output a current to a power consuming device 120. For example, the first TFT 102A is configured to output a current from supply voltage V_{DD} 112 to anode 122A of the power consuming device 120. The second TFT is configured to provide a control voltage to the first TFT for controlling an amount of the current. For example, the second TFT 104A is configured to provide a control voltage (from control voltage line 108) to the first TFT 102A, and a difference between the control voltage and the voltage of the power consuming device 120 (e.g., V_{GS} between gate voltage of the TFT 102A and source of the TFT 102A) (along with value of supply voltage V_{DD} 112) controls an amount of the current being outputted to the power consuming device 120. In some embodiments, the amount of current is 1-50 μA. For example, the current is based on pixel size. If the current density of the power consuming device is 0.01-0.02 μA/μm² and a pitch of the pixel is 10-50 μm, then the amount of current is 1-50 μA. As another example, the power consuming device comprises an infrared emitting device of an infrared scene projector. The Gth is 1×10⁻⁷ W/K. If the temperature is raised by 500 K, then the dissipated power would be to be 500 K×Gth=50 μW. If the resistance of the infrared emitting device is 1 mega-ohm, the corresponding current would be 7 μA. For the same parameters, if the dissipated power is 2.5 mW, then the corresponding current would be 50 μA. For an HD array (e.g., 1920×1080), the entire array may dissipate 5 KW of power.

In some embodiments, the storage capacitor is configured to store the control voltage. For example, the storage capacitor 106A is configured to store the control voltage (e.g., a difference between the control voltage and the voltage of the power consuming device 120, V_{Gs} between gate voltage of the TFT 102A and source of the TFT 102A, a voltage at the gate of the TFT 102A). The storage capacitor may advantageously keep a respective first TFT at a desired transistor operation region (for providing the amount of current for controlling the power consuming device 120) (e.g., after a respective second TFT de-couples the control voltage line from the first TFT).

In some embodiments, the circuit 100 comprises a source follower, and the source follower comprises the first TFT. For example, the first TFT 102A forms a source follower because the first TFT 102A is receives a control voltage, and in response to the control voltage, outputs a current. The source follower may advantageously outputs a current across a variety of power consuming device impedances.

As illustrated in FIG. 1, voltages of the anodes 122A-122E for controlling the electrochemical bath for electroplating are controlled by an amount of current being outputted to a respective anode (via a respective first TFT as described above). By using an array of transistors (such as TFT technology) and the disclosed pixels, the circuit 100 advantageously may improve control of electroplating by improved control of the current (via first and second TFTs) provided to the power consuming device, compared to a power consuming device that receives current from a single transistor.

Although the disclosed circuits are illustrated with respect to one pixel or one row comprising a specific number of pixels, it should be appreciated that these circuits may comprise more than one row of pixels and/or more than one column of pixels (each column corresponding to a control voltage line).

As an example of more than one column of pixels along a same row, in some embodiments, the circuit further comprises a third TFT configured to output a second current to a second power consuming device, a fourth TFT configured to couple a second control voltage to the third TFT, the second control voltage controlling an amount of the second current, and a second storage capacitor coupled to the third and fourth TFTs for storing the second control voltage. In response to receiving a row control signal: the second TFT couples the first control voltage to the first TFT, and the fourth TFT couples the second control voltage to the third TFT. As an example, the row 110 may be coupled to a second TFT (other than second TFTs 104A-104E), and this second TFT may be connected to a second control voltage line (other than control voltage line 108) for controlling a first TFT (other than first TFTs 102A-102E) and an amount of a second current to be outputted a power consuming device. These first and second TFTs may connect to a second storage capacitor for storing the second control voltage.

As an example of more than one row of pixels along a same column, in some embodiments, the circuit further comprises a third TFT configured to output a second current to a second power consuming device, a fourth TFT configured to couple the control voltage to the third TFT, the control voltage controlling an amount of the second current, and a second storage capacitor coupled to the third and fourth TFTs for storing the second control voltage. As an example, a second row (other than row 110) may be coupled to a second TFT (other than second TFTs 104A-104E), and this second TFT may be connected to the control voltage line 108 for controlling a first TFT (other than first TFTs 102A-102E) and an amount of a second current to be outputted a power consuming device. These first and second TFTs may connect to a second storage capacitor for storing the second control voltage.

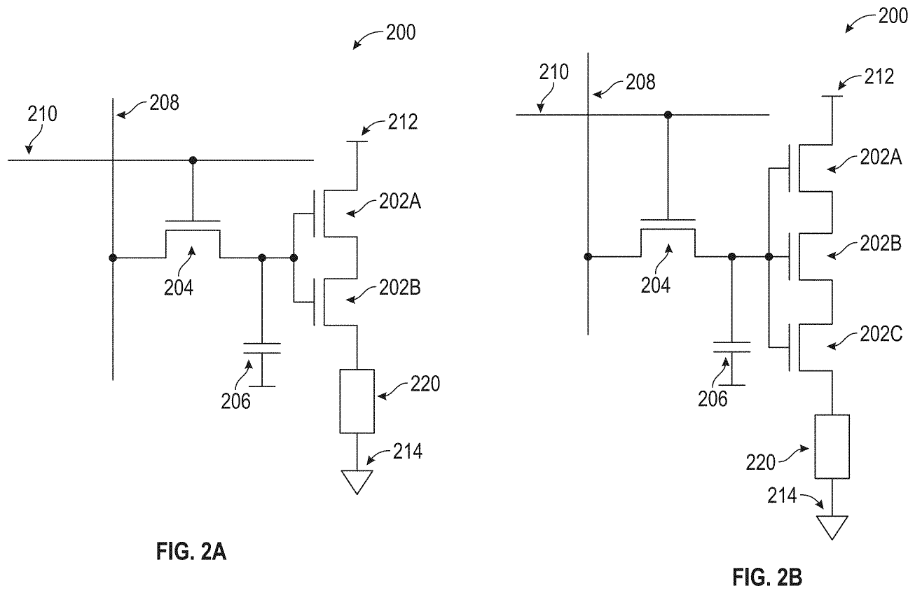

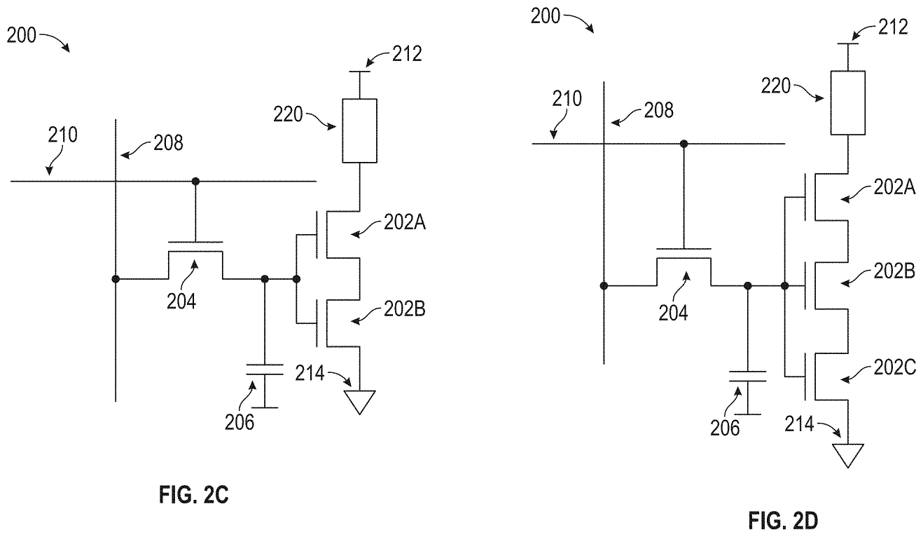

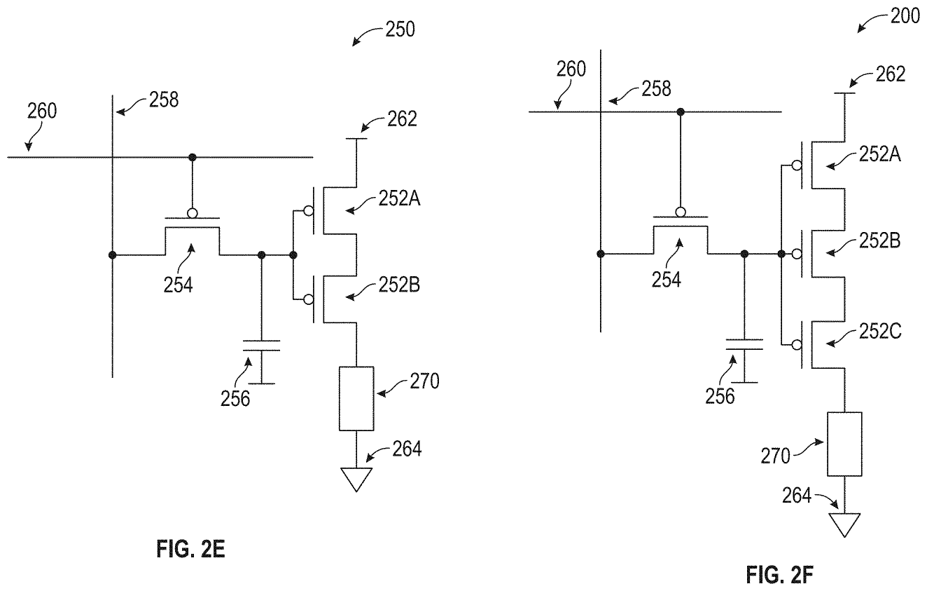

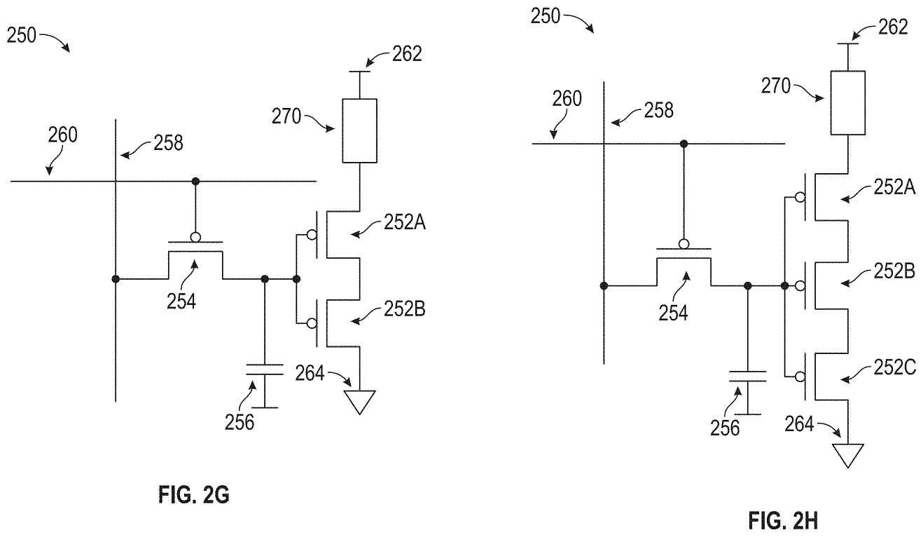

FIGS. 2A-2H illustrate exemplary circuits 200 and 250 for controlling a power consuming device, according to embodiments of the disclosure. As illustrated in FIG. 2A, the circuit 200 comprises first TFT 202A, second TFT 204, third TFT 202B, storage capacitor 206, control voltage line 208, row 210, power supply V_{DD} 212, and ground voltage 214. In some embodiments, in FIGS. 2A-2D, the second TFT 204 corresponds to one of second TFTs 104A-104E, the storage capacitor 206 corresponds to one of storage capacitors 106A-106E, the power consuming device 220 to power consuming device 120, power supply V_{DD} 212 corresponds to power supply V_{DD} 112, and ground voltage 214 corresponds to ground voltage 114.

In some embodiments, the first TFT 202A and the third TFT 202B are connected in series (as illustrated in FIG. 2A) and configured to provide a current to the power consuming device 220, and the second TFT 204 is configured to couple the control voltage line 208 to the first TFT 202A and the third TFT 202B. In some embodiments, the power consuming device 220 (e.g., an infrared emitting device) has a higher input impedance (e.g., at least 500 kilo-ohms). By connecting the first and third TFTs in series and using the first and third TFTs to output the current to the power consuming device, the output impedance of the pixel is increased. The increased output impedance may advantageously allow better control of the current to the power consuming device by increasing a drain-to-source voltage across the current outputting device(s) (e.g., first and third TFTs). In some embodiments, the output impedance of the pixel is half of the impedance of the power consuming device.

FIGS. 2B-2H illustrate other exemplary circuits for controlling the power consuming devices that may achieve the above-mentioned benefits. As illustrated in FIG. 2B, the circuit 200 further comprises a fourth TFT 202C, and the first TFT 202A, the third TFT 202B, and the fourth TFT 202C are connected in series and configured to provide a current to the power consuming device 220, and the second TFT 204 is configured to couple the control voltage line 208 to the first TFT 202A, the third TFT 202B, and the fourth TFT 202C. As illustrated in FIG. 2C, the first TFT 202A and the third TFT 202B are connected in series and configured to provide a current to the power consuming device 220 (via the drain of TFT 202A, as opposed to the source of a TFT in FIGS. 2A and 2B), and the second TFT 204 is configured to couple the control voltage line 208 to the first TFT 202A and the third TFT 202B. As illustrated in FIG. 2D, the circuit 200 further comprises a fourth TFT 202C, and the first TFT 202A, the third TFT 202B, and the fourth TFT 202C are connected in series and configured to provide a current to the power consuming device 220 (via the drain of TFT 202A, as opposed to the source of a TFT in FIGS. 2A and 2B), and the second TFT 204 is configured to couple the control voltage line 208 to the first TFT 202A, the third TFT 202B, and the fourth TFT 202C.

It should also be appreciated that the disclosed circuits may comprise PMOS devices for controlling a power consuming device. As illustrated in FIG. 2E, the circuit 250 comprises first PMOS TFT 252A, second PMOS TFT 254, third PMOS TFT 252B, storage capacitor 256, control voltage line 258, row 260, power supply V_{DD} 262, and ground voltage 264. In some embodiments, in FIGS. 2E-2H, the second PMOS TFT 254 corresponds to one of second TFTs 104A-104E, the storage capacitor 256 corresponds to one of storage capacitors 106A-106E, the power consuming device 270 to power consuming device 120, power supply V_{DD} 262 corresponds to power supply V_{DD} 112, and ground voltage 264 corresponds to ground voltage 114. In these examples, a source-to-gate voltage is provided via the control voltage line 258 to the PMOS devices for outputting a current to the power consuming device, and a complement row control signal on row 260 (compared to a row control signal for controlling a second NMOS TFT) is used for coupling, via a second PMOS TFT (e.g., second PMOS TFT 252), the control voltage line to the first TFT.

As illustrated in FIG. 2E, the first PMOS TFT 252A and the third PMOS TFT 252B are connected in series and configured to provide a current to the power consuming device 270, and the second PMOS TFT 254 is configured to couple the control voltage line 258 to the first PMOS TFT 252A and the third TFT 252B. As illustrated in FIG. 2F, the circuit 250 further comprises a fourth PMOS TFT 252C, and the first PMOS TFT 252A, the third PMOS TFT 252B, and the fourth PMOS TFT 252C are connected in series and configured to provide a current to the power consuming device 270, and the second PMOS TFT 254 is configured to couple the control voltage line 258 to the first PMOS TFT 252A, the third PMOS TFT 252B, and the fourth PMOS TFT 252C. As illustrated in FIG. 2G, the first PMOS TFT 252A and the third PMOS TFT 252B are connected in series and configured to provide a current to the power consuming device 270 (via the source of PMOS TFT 252A, as opposed to the drain of a PMOS TFT in FIGS. 2E and 2F), and the second PMOS TFT 254 is configured to couple the control voltage line 258 to the first PMOS TFT 252A and the third PMOS TFT 252B. As illustrated in FIG. 2H, the circuit 250 further comprises a fourth PMOS TFT 252C, and the first PMOS TFT 252A, the third PMOS TFT 252B, and the fourth PMOS TFT 252C are connected in series and configured to provide a current to the power consuming device 270 (via the source of PMOS TFT 252A, as opposed to the drain of a PMOS TFT in FIGS. 2E and 2F), and the second PMOS TFT 254 is configured to couple the control voltage line 258 to the first PMOS TFT 252A, the third PMOS TFT 252B, and the fourth PMOS TFT 252C.

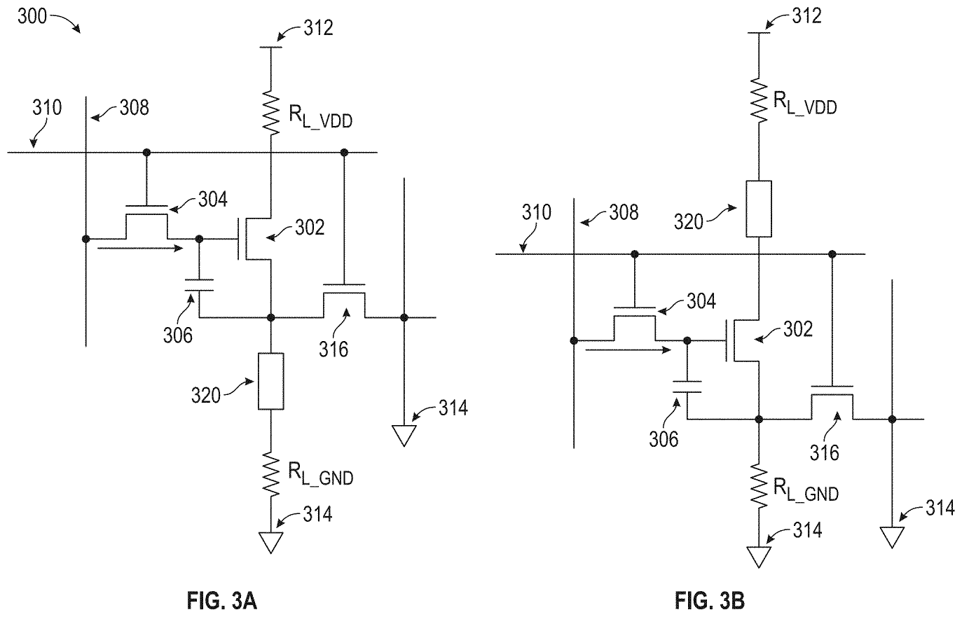

FIGS. 3A-3B illustrate exemplary circuits for controlling a power consuming device, according to embodiments of the disclosure. As illustrated in FIG. 3A, the circuit 300 comprises first TFT 302, second TFT 304, third TFT 316, storage capacitor 306, control voltage line 308, row 310, power supply V_{DD} 312, and ground voltage 314. In some embodiments, in FIGS. 3A-3B, the second TFT 304 corresponds to one of second TFTs 104A-104E, the storage capacitor 306 corresponds to one of storage capacitors 106A-106E, the power consuming device 320 to power consuming device 120, power supply V_{DD} 312 corresponds to power supply V_{DD} 112, and ground voltage 314 corresponds to ground voltage 114.

In some embodiments, the third TFT 316 is configured to couple the power consuming device 320 to the ground voltage 314. For example, as illustrated, the third TFT 316 is coupled between the power consuming device 320 and ground voltage 314 and is coupled to row 308. When the row control signal corresponding to row 308 turns on the second TFT 304, the third TFT 316 is also turned on, coupling the power consuming device 320 to the ground voltage 314.

In some instances, the power consuming device 320 may receive a high amount of current (e.g., greater than 1 μA, such as 1-50 μA). Depending on the location of the power consuming device 320, a voltage drop may be created across resistance R_{L_VDD}, effective resistance between power supply V_{DD} 312 and first TFT 302, and created across resistance R_{L_GND}, effective resistance between the power consuming device 320 and ground voltage 314. The voltage drop may cause device control to be non-uniform because the effective resistances and voltage drops may be dependent on a location of a power consuming device. This non-uniformity may increase with size of a TFT array (e.g., panel size).

By coupling the power consuming device 320 to ground voltage 314 via third TFT 316, the effects of resistance R_{L_GND} may be reduced (e.g., a voltage drop between the power consuming device 320 and ground voltage 314 may be reduced), allowing device control to be more uniform and location-independent (e.g., during row time when row control signal selects a pixel, outside of row time). In some embodiments, a current through the third TFT 316 is small, compared to a current outputted to the power consuming device 320, hence the effect of resistance would be reduced with this additional parallel path.

It should be appreciated that the power consuming device may be coupled differently than illustrated in FIG. 3A. For example, as illustrated in FIG. 3B, the first TFT 302 couples to the power consuming device 320 via the drain of TFT 302, as opposed to the source of the TFT 302 in FIG. 3A.

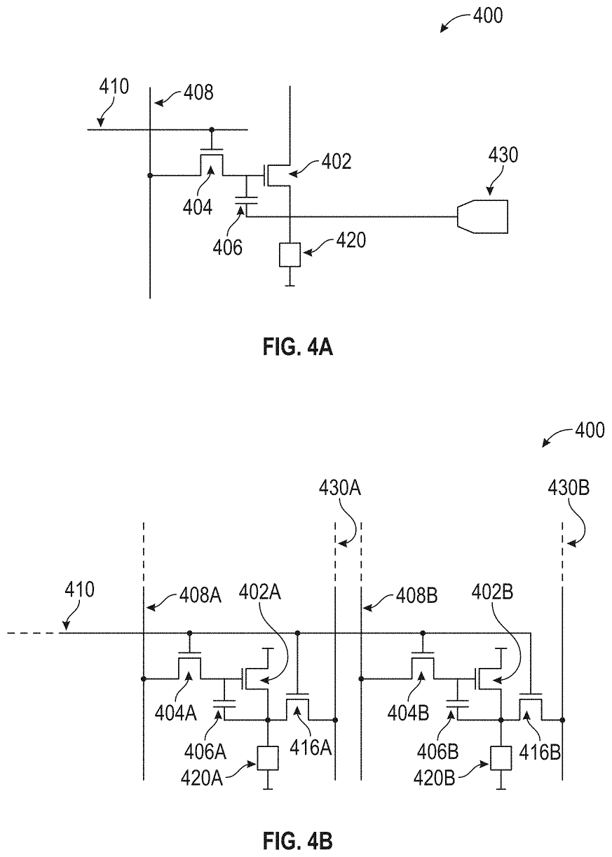

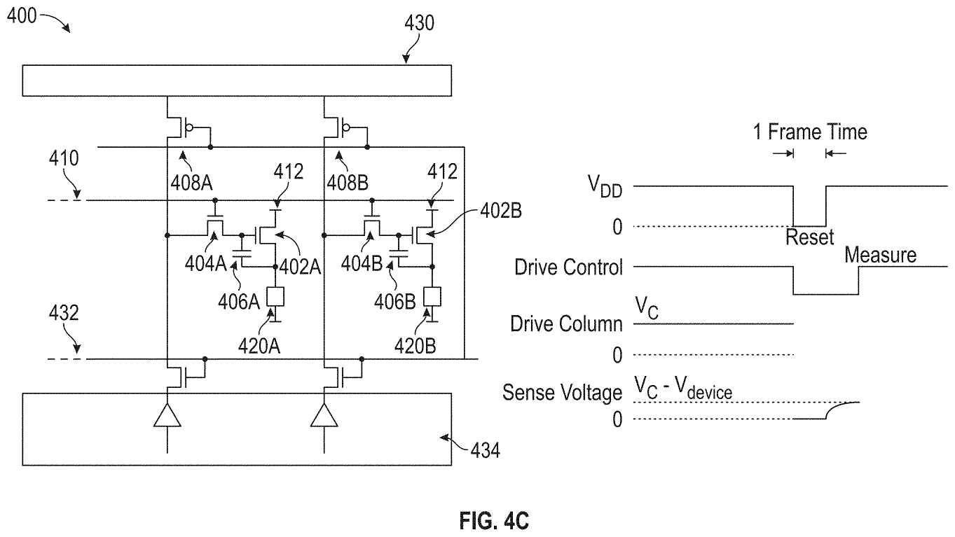

FIGS. 4A-4C illustrate exemplary circuits 400 for controlling a power consuming device, according to embodiments of the disclosure. As illustrated in FIG. 4A, the circuit 400 comprises first TFT 402, second TFT 404, storage capacitor 406, control voltage line 408, and row 410. In some embodiments, in FIGS. 4A-4C, the first TFT 402 corresponds to one of first TFTs 102A-102E, the second TFT 404 corresponds to one of second TFTs 104A-104E, the storage capacitor 406 corresponds to one of storage capacitors 106A-106E, the power consuming device 420 corresponds to power consuming device 120.

In some embodiments, the circuits 400 comprises an element for advantageously sensing (and monitoring) a voltage of the power consuming device 420. For example, it may be important to sense when a particular pixel has finished with an operation of an associated power consuming device. Using electrochemical deposition (e.g., the power consuming device 420 is an electrochemical bath) as an example, deposition may be finished when the deposited metal shorts an anode to a cathode. In such embodiments, sensing a given anode voltage would allow not just the end of run condition but may also advantageously monitor the growth rate mid-course. Using as infrared scene projector as another example (e.g., the power consuming device 420 is an infrared emitting device), a voltage and power of an emitting device may be monitored.

Although an example of the circuits 400 is described with respect to an electrochemical bath, it should be appreciated that the electrochemical bath is provided to illustrate circuitries for controlling a power consuming device. It should be appreciated that the disclosed power consuming devices can be a different kind of power consuming device (configured to receive a current provided by a disclosed circuit), such as an infrared emitting device, light emitting diodes assembled onto TFT backplanes (e.g., mini LEDs, micro LEDs for outdoor signature and display), pixelated thermionic x-ray sources, arrayed sources for active electromagnetic, acoustic, or other energetic phenomena.

As illustrated in FIG. 4A, in some embodiments, the circuit 400 comprises a test pad 430 that can be probed to provide a measurement of the power consuming device 420. As illustrated in FIG. 4B, in some embodiments, the circuit 400 comprises a first pixel (first TFT 402A, second TFT 404A, storage capacitor 406A) coupled to a first control voltage line 408A and a second pixel (first TFT 402B, second TFT 404B, storage capacitor 406B) coupled to a second control voltage line 408B. The first pixel comprises a third TFT 416A and the second pixel comprises a third TFT 416B. The TFT 416A is configured to couple the power consuming device 420A to sensing line 430A for measuring the power consuming device 420A, and the TFT 416 is configured to couple the power consuming device 420B to sensing line 430B for measuring the power consuming device 430B. In some embodiments, each sensing line is coupled to a respective measurement pad for measuring a respective power consuming device.

As illustrated in FIG. 4C, in some embodiments, the circuit 400 comprises a first pixel (first TFT 402A, second TFT 404A, storage capacitor 406A) coupled to a first control voltage line 408A and a second pixel (first TFT 402B, second TFT 404B, storage capacitor 406B) coupled to a second control voltage line 408B. The first control voltage line 408A may advantageously function as a sensing line for the first power consuming device 420A, and the second control voltage line 408B may advantageously function as a sensing line for the second power consuming device 420B.

In some embodiments, as illustrated in FIG. 4C, the circuit 400 comprises a drive control line 432 that causes the control voltage lines to selectively couple to control voltage drivers 434 (for providing a control voltage to a respective control voltage line) or selectively couple the control voltage lines to sensing circuitry 430. In some embodiments, the sensing circuitry 430 comprises a readout integrated circuit (ROIC). For example, during power consumption device operation, as illustrated in FIG. 4C, when the drive control line signal is high, the control voltage lines couple to control voltage drivers 434 and de-couples from the sensing circuitry 430. During this time, power supply 412 is set to V_{DD} for providing current to the power consuming devices, and the sensing circuitry 430 may be disabled.

When the drive control line signal is low (during sensing), the control voltage lines couple to sensing circuitry 430 and de-couples from the control voltage drivers 434. During this time, the control voltage drivers 434 may be disabled (e.g., by setting them to a high impedance state), and the sensing circuitry 430 senses the control voltage lines. For a period of time (e.g., one frame time), the power supply 412 is set to zero, establishing a measurement initial condition and setting a voltage of a respective power consuming device to zero. During this time, the storage capacitor voltage follows the control voltage line voltage from a previous driving phase, V_{c}. After the period of time (e.g., after the one frame time), the power supply 412 may be pulled up to V_{DD}, and the power consuming device voltage settles back to its previous voltage during the last driving phase. After a transient period (determined by the control voltage line parasitic resistance/capacitance), the control voltage line voltage settles to the value V_{c}-V_{device}. This voltage is sensed by the sensing circuitry 430 to determine V_{device}, the voltage of a power consuming device. Exemplary waveforms of this sensing operation is illustrated in FIG. 4C.

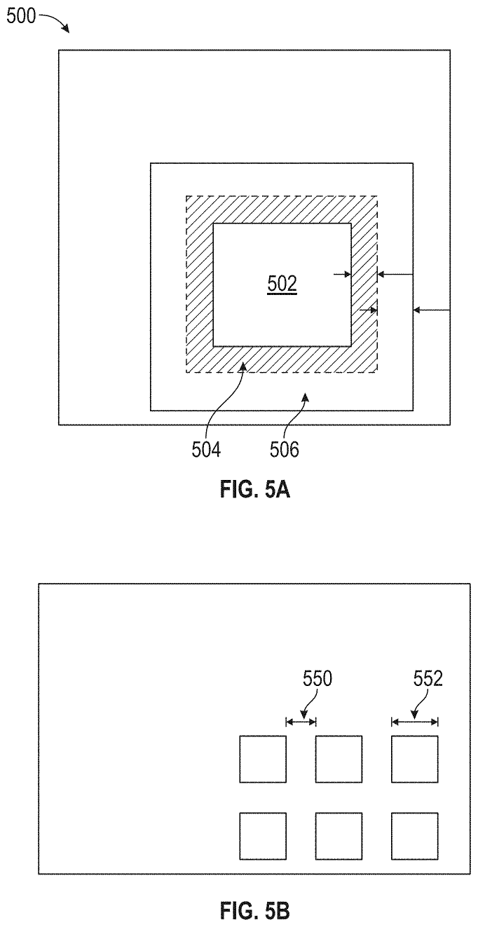

FIGS. 5A-5B illustrate exemplary structures of a circuit for controlling a power consuming device, according to embodiments of the disclosure. In some embodiments, the circuit 500 comprises a panel, which comprises circuitries described with respect to FIGS. 1-4C. In some embodiments, a chip on flex attachment is used for connection. By using an array of transistors (such as TFT technology on a panel) and the disclosed pixels, the circuit advantageously may improve control of electroplating by improved control of the current (via first and second TFTs) provided to the power consuming device, compared to a power consuming device that receives current from a single transistor.

In some embodiments, the panel comprises an active area 502. In some embodiments, the active area 502 comprises 540×480 pixels at a 50 μm pitch. In some embodiments, the active area 502 has an area of 27 mm×24 mm. In some embodiments, the active area 502 comprises 480×480 pixels at a 30 μm pitch. In some embodiments, the active area 502 comprises 512×480 pixels at a 50 μm pitch, which may advantageously correspond to a specific driver circuitry. In some embodiments, the size and pitch of the active area is determined by input and output size of circuitries coupled to the active area. In some embodiments, the panel comprises a keep out zone 504, which is a 5 mm wide border surrounding the active area 502. In some embodiments, the panel comprises a border 506, and a width of the border 506 is between 5-10 mm. In some embodiments, the border 506 comprises flex attachments for connections to the circuit 500.

FIG. 5B illustrates exemplary pixels of a circuit for controlling a power consuming device, according to embodiments of the disclosure. As an example, FIG. 5B illustrates six pixels, and each pixel may correspond to a pixel described with respect to FIGS. 1-4C. In some embodiments, a distance between adjacent pixels has a width 550. In some embodiments, width 550 is 20 μm. In some embodiments, a pixel has a width 552. In some embodiments, width 552 is 30 μm.

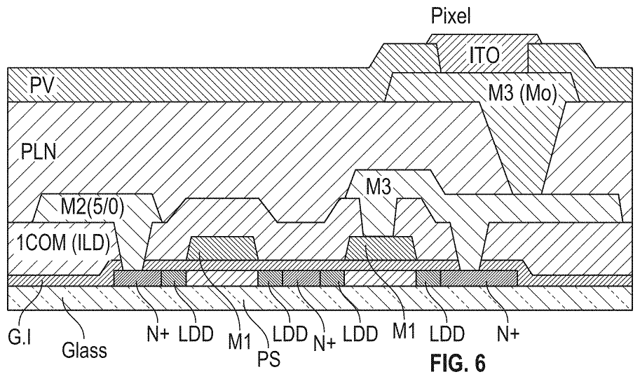

FIG. 6 illustrates an exemplary structure of a circuit for controlling a power consuming device, according to embodiments of the disclosure. In some embodiments, the circuit 600 comprises a pixel comprising indium tin oxide (ITO) contacts. Below a top contact, the circuit 600 comprises a SiNx passivation (PV) layer. Below the SiNx passivation layer, the circuit 600 comprises an acrylic planarizing layer (PLN). The circuit 600 comprises metal layers M3, M2, M1 that electrically couple to the ITO contacts. The circuit 600 comprises a glass substrate (glass). In some embodiments, the disclosed TFTs (e.g., first TFTs 102A-102E, second TFTs 104A-104E, TFTs described with respect to FIGS. 1-4C) are disposed on the glass substrate.

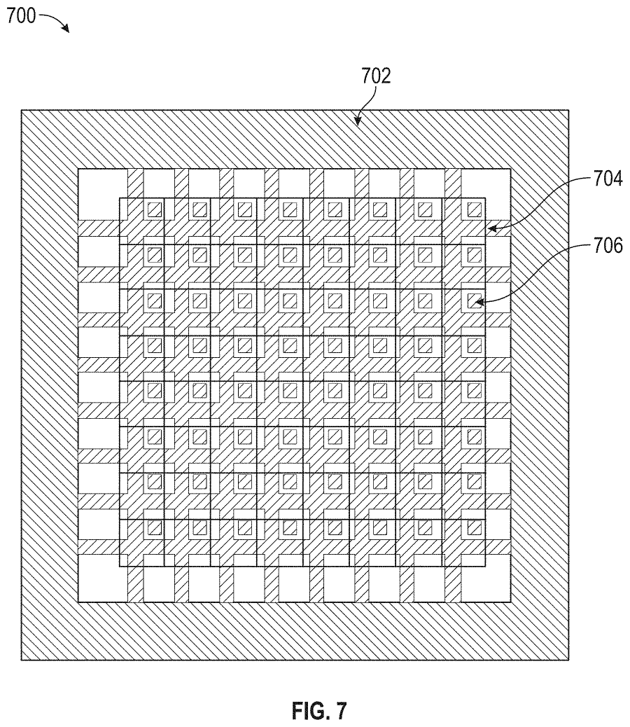

FIG. 7 illustrates an exemplary structure of a circuit 700 for controlling a power consuming device, according to embodiments of the disclosure. In some embodiments, the circuit 700 comprises a circuit described with respect to FIGS. 1-6. Because of a high current (e.g., greater than 1 μA, such as 1-50 μA) loading presented to each power consuming device, the metal layers of circuit 700 may be used to advantageously provide the V_{DD} (e.g., power supply V_{DD} 112) or ground voltages (e.g., ground voltage 114). For example, at a nominal output current of 25 μA for a power consuming device, the entire circuit 700 may sink over 6A.

In some embodiments, the circuit 700 comprises a ring 702 and a mesh 704 coupled to a power supply or ground voltage for providing the current to the circuit 700. In some embodiments, the ring 702 has resistance of up to 1 ohm on one side of the ring. The ring 702 may be sized to meet this resistance value. In some embodiments, the mesh 704 has a pitch of 10-200 μm. The pitch of the mesh 704 may be determined by pixel pitch. In some embodiments, the mesh 704 comprises a metal 3 layer (M3), and the mesh 704 covers an array of pixels 706 (delineated by the fine line square for illustration purposes) (for providing and sinking the high current for the power consuming device), as illustrated in FIG. 7. The ring 702 and the mesh 704 advantageously increase uniformity of V_{DD} (e.g., power supply V_{DD} 112) or ground voltages (e.g., ground voltage 114) for each pixel 706. Compared to using a conductive plate for power delivery (e.g., in a display device), the mesh 704 allow the pixels 706 to be exposed, while increasing uniformity of power delivery, which may be advantageous for some power consuming devices or some MEMS structures. For example, the power consuming device comprises a radiation emitting device (e.g., near-infrared emitting device), and the mesh 704 is more transparent to radiation from the emitting devices.

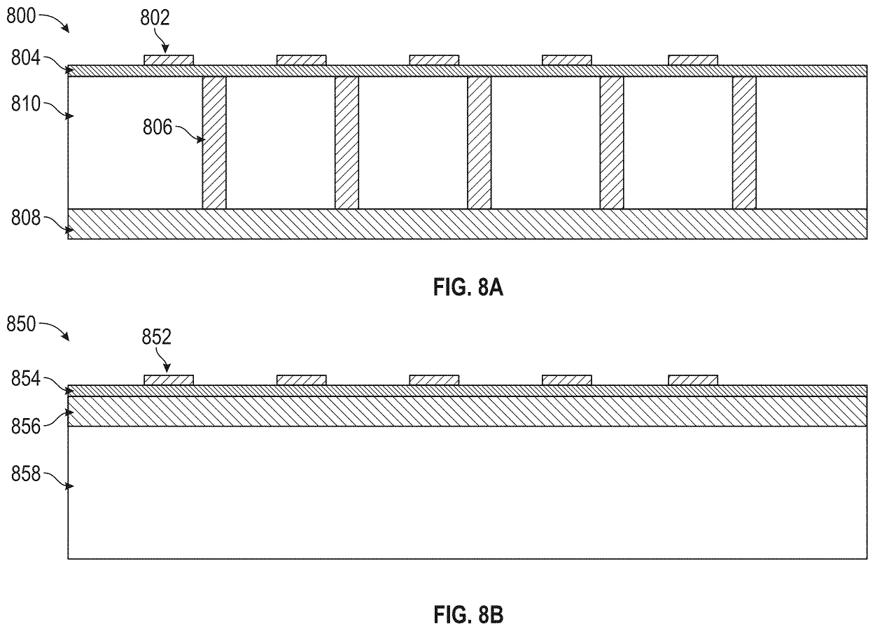

FIGS. 8A-8B illustrate exemplary structures of a circuit for controlling a power consuming device, according to embodiments of the disclosure. In some embodiments, the circuit 800 comprises a circuit described with respect to FIGS. 1-7. In some embodiments, the circuit 800 comprises power consuming devices 802. In some embodiments, power consuming devices 802 comprise anodes of an electrochemical bath. In some embodiments, the circuit 800 comprises a device layer 804. In some embodiments, the device layer 804 comprises low-temperature polycrystalline silicon (LTPS) circuits, which comprise the circuits described with respect to FIGS. 1-7. In some embodiments, the circuit 800 comprises filled via 806 coupled to the device layer 804 and backside metal 808, and the filled via 806 is created by laser drilling through the glass layer 810 (e.g., glass substrate). This structure may be used for power delivery in addition or in lieu of the ring 702 and/or mesh 704.

Although examples of FIGS. 8A and 8B are described with respect to an electrochemical bath, it should be appreciated that the electrochemical bath is provided to illustrate circuitries for controlling a power consuming device. It should be appreciated that the disclosed power consuming devices can be a different kind of power consuming device (configured to receive a current provided by a disclosed circuit), such as an infrared emitting device, light emitting diodes assembled onto TFT backplanes (e.g., mini LEDs, micro LEDs for outdoor signature and display), pixelated thermionic x-ray sources, arrayed sources for active electromagnetic, acoustic, or other energetic phenomena.

In some embodiments, the circuit 850 comprises a circuit described with respect to FIGS. 1-7. In some embodiments, the circuit 850 comprises power consuming devices 852. In some embodiments, power consuming devices 852 comprise anodes of an electrochemical bath. In some embodiments, the circuit 850 comprises a device layer 854. In some embodiments, the device layer 854 comprises low-temperature polycrystalline silicon (LTPS) circuits, which comprise the circuits described with respect to FIGS. 1-7. In some embodiments, the circuit 850 comprises metal layer 856 coupled to device layer 854 and disposed on glass layer 858 (e.g., glass substrate). In some embodiments, the metal layer 856 comprises metal 0 (M0) layer metal, and the metal layer 856 has a 1 μm thickness or less. A LTPS process may be tuned accordingly to accommodate the metal layer 856, which may be embedded below the device layer 854. This structure may be used for power delivery in addition or in lieu of the ring 702 and/or mesh 704. This structure may advantageously lower cost by removing a need for a drilling process (for creating filled via 806).

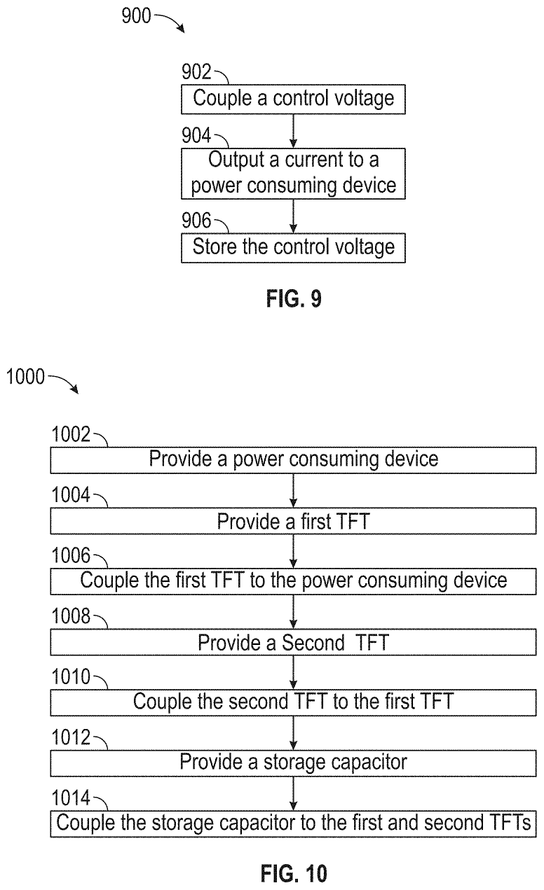

FIG. 9 illustrates an exemplary method 900 for controlling a power consuming device, according to embodiments of the disclosure. In some embodiments, the method 900 is method of operating a disclosed circuit (e.g., circuit 100, circuit 200, circuit 300, circuit 400, circuit 500, circuit 600, circuit 700, circuit 800, circuit 850). For the sake of brevity, some elements and advantages associated with these systems are not repeated here. Although the method 900 is illustrated as including the described steps, it is understood that different order of step, additional step (e.g., combination with other methods disclosed herein), or less step may be included without departing from the scope of the disclosure.

In some embodiments, the method 900 comprises coupling, via the second TFT, a control voltage to a first TFT (step 902). For example, as described with respect to FIGS. 1-4C, a control voltage (from a control voltage line) is coupled to a first TFT (e.g., one of first TFTs 102A-102E) by using a row control signal to turn on a second TFT (e.g., one of second TFTs 104A-104E).

In some embodiments, the method 900 comprises in response to coupling to the control voltage, outputting, via the first TFT, a current to a power consuming device (step 904). In some embodiments, the control voltage controls an amount of the current. For example, as described with respect to FIGS. 1-4C, a control voltage (from a control voltage line) is coupled to a first TFT (e.g., one of first TFTs 102A-102E). In response to the control voltage coupling to the first TFT, the TFT outputs a current a power consuming device (e.g., power consuming device 120). The gate-to-source voltage, which is affected by the control voltage, controls an amount of current being outputted from the first TFT.

In some embodiments, the power consuming device comprises an infrared emitting device. The infrared emitting device is configured to emit infrared radiation in response to receiving the current from the first TFT. In some embodiments, the power consuming device comprises an electrochemical bath. The current is provided by the first TFT to the electrochemical bath for electroplating. In some embodiments, the power consuming device comprises light emitting diodes assembled onto TFT backplanes (e.g., mini LEDs, micro LEDs for outdoor signature and display), pixelated thermionic x-ray sources, arrayed sources for active electromagnetic, acoustic, or other energetic phenomena.

In some embodiments, the method 900 comprises storing, via a storage capacitor, the control voltage (step 906). For example, as described with respect to FIGS. 1-4C, a storage capacitor (e.g., one of storage capacitors 106A-106E) stores the control voltage being coupled to a first TFT (e.g., one of first TFTs 102A-102E).

In some embodiments, the method 900 further comprises coupling, via a third TFT, the power consuming device to a ground voltage. For example, as described with respect to FIGS. 3A-3B, the power consuming device 320 is coupled to ground voltage 314 via the TFT 316. In some embodiments, the method 900 further comprises sensing a voltage of the power consuming device. For example, as described with respect to FIGS. 4A-4C, the voltage of the power consuming device is sensed via a test pad and/or sensing circuitry.

FIG. 10 illustrates an exemplary method 1000 for manufacturing a circuit for controlling a power consuming device, according to embodiments of the disclosure. In some embodiments, the method 1000 is method of manufacturing a disclosed circuit (e.g., circuit 100, circuit 200, circuit 300, circuit 400, circuit 500, circuit 600, circuit 700, circuit 800, circuit 850). For the sake of brevity, some elements and advantages associated with these systems are not repeated here. Although the method 1000 is illustrated as including the described steps, it is understood that different order of step, additional step (e.g., combination with other methods disclosed herein), or less step may be included without departing from the scope of the disclosure.

In some embodiments, the method 1000 comprises providing a power consuming device (step 1002). For example, as described with respect to FIGS. 1-8, a power consuming device (e.g., power consuming device 120) is provided. In some embodiments, the method 100 comprises providing a first TFT (step 1004). For example, as described with respect to FIGS. 1-8, a first TFT (e.g., one of first TFTs 102A-102E) is provided (via a technology process described with respect to the TFTs).

In some embodiments, the method 1000 comprises coupling the first TFT to the power consuming device (step 1006). For example, as described with respect to FIGS. 1-8, a first TFT (e.g., one of first TFTs 102A-102E) is coupled to a power consuming device (e.g., power consuming device 120). In some embodiments, the first TFT is configured to output a current to the power consuming device.

In some embodiments, the method 1000 comprises providing a second TFT (step 1008). For example, as described with respect to FIGS. 1-8, a second TFT (e.g., one of second TFTs 104A-104E) is provided (via a technology process described with respect to the TFTs). In some embodiments, the method 1000 comprises coupling the second TFT to the first TFT (step 1010). For example, as described with respect to FIGS. 1-8, a second TFT (e.g., one of second TFTs 104A-104E) is coupled to a gate of a first TFT (e.g., one of first TFTs 102A-102E). In some embodiments, the second TFT is configured to couple a control voltage to the first TFT, the control voltage controlling an amount of the current.

In some embodiments, the method 1000 comprises providing a storage capacitor (step 1012). For example, as described with respect to FIGS. 1-8, a storage capacitor (e.g., one of storage capacitor 106A-106E) is provided (via a described technology process). In some embodiments, the storage capacitor is configured to store the control voltage. In some embodiments, the method 1000 comprises coupling the storage capacitor to the first and second TFTs (step 1014). For example, as described with respect to FIGS. 1-8, a storage capacitor (e.g., one of storage capacitor 106A-106E) is coupled to a first TFT (e.g., one of first TFTs 102A-102E) and a second TFT (e.g., one of second TFTs 104A-104E).

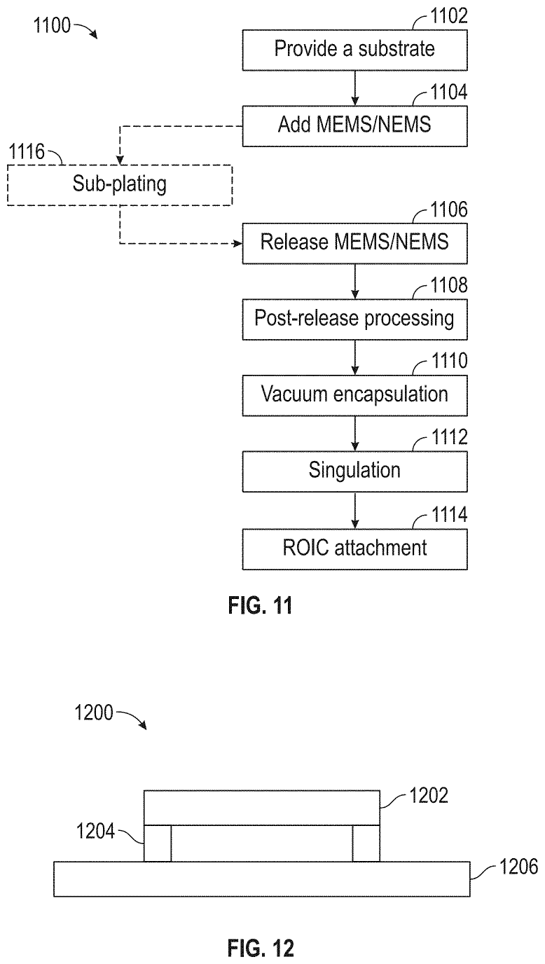

FIG. 11 illustrates a method 1100 of manufacturing an electromechanical system, in accordance with an embodiment. As non-limiting examples, the electromechanical system could be associated with the devices (e.g., circuit 100, circuit 200, circuit 300, circuit 400, circuit 500, circuit 600, circuit 700, circuit 800, circuit 850) or systems described herein. To manufacture an electromechanical system, all or some of the process steps in method 1100 could be used and used in a different order. As a non-limiting example, Step 1114 could be performed before Step 1112. In some embodiments, the method 900 and/or method 1000 can be performed with method 1100.

Method 1100 includes Step 1102, providing a substrate. In some embodiments, the substrate is made of glass. In some embodiments, the substrate is low temperature polycrystalline silicon. In some embodiments, the substrate is a borosilicate that contains additional elements to fine tune properties. An example of a borosilicate is by Corning Eagle™, which produces an alkaline earth boro aluminosilicate (a silicate loaded with boron, aluminum, and various alkaline earth elements). Other variations are available from Asahi Glass' or Schott™.

In some embodiments, a flat panel glass process is used to manufacture the electromechanical system. In some embodiments, a liquid crystal display (LCD) process is used to manufacture the electromechanical system. In some embodiments, an OLED display process or an x-ray panel process is used. Employing a flat panel glass process may allow for increased substrate sizes, thereby allowing for a higher number of electromechanical systems per substrate, which reduces processing costs. Substrate sizes for “Panel Level” can include 620 mm×750 mm, 680 mm×880 mm, 1100 mm×1300 mm, 1300 mm×1500 mm, 1500 mm×1850 mm, 1950 mm×2250 mm, and 2200 mm×2500 mm. Further, thin film transistors (TFTs) in panel level manufacturing can also reduce cost and so, for example, LCD-TFT processes can be beneficial.

Method 1100 includes Step 1104, adding MEMS to the substrate. Although MEMS is used to describe the addition of structures, it should be appreciated that other structures could be added without deviating from the scope of this disclosure. In embodiments using panel level processing, the MEMS structures may be added using an LCD-TFT process.

Step 1104 may be followed by optional Step 1116, sub-plating. Step 1116 may be used when the substrate is larger than the processing equipment used in subsequent steps. For example, if using a panel level process (such as LCD), some embodiments will include (at Step 1104) cutting the panel into wafer sizes to perform further processing (using, for example, CMOS manufacturing equipment). In other embodiments, the same size substrate is used throughout method 1100 (i.e., Step 1116 is not used).

Method 1100 includes Step 1106, releasing the MEMS from the substrate.

Method 1100 includes Step 1108, post-release processing. Such post-release processing may prepare the MEMS structure for further process steps, such as planarization. In wafer-level processing, planarization can include chemical mechanical planarization. In some embodiments, the further process steps include etch back, where a photoresist is spun onto the topography to generate a more planar surface, which is then etched. Higher control of the etch time can yield a smoother surface profile. In some embodiments, the further process steps include “spin on glass,” where glass-loaded organic binder is spun onto the topography and the result is baked to drive off organic solvents, leaving behind a surface that is smoother.

Method 1100 includes Step 1110, vacuum encapsulation of the MEMS structure, where necessary. Vacuum encapsulation may be beneficial to prolong device life.

Method 1100 includes Step 1112, singulation. Some embodiments may include calibration and chip programming, which may take into account the properties of the sensors. Methods described herein may be advantageous in glass substrate manufacturing processes because uniformity in glass lithography capabilities is limited. As a further advantage, glass has a lower thermal conductivity and so a glass substrate can be a better thermal insulator; by manufacturing thin structures separating a bolometer pixel from a glass substrate, embodiments herein may better serve to thermally isolate the glass bolometer pixel from the packaging environment.

Method 1100 includes Step 1114, attachment of a readout integrated circuit (ROIC) and flex/PCB attachment. As non-limiting examples, the readout circuits could be associated with devices or systems described herein. Processes and devices described herein may have the further advantage that the area required for signal processing can be much smaller than the sensing area which is dictated by the sensing physics. Typically, sensors are integrated on top of CMOS circuitry, and area driven costs lead to a technology node that is not optimal for the signal processing task. Processes described herein can use a more suitable CMOS and drive down the area required for signal processing, freeing the sensor from any area constraints by leveraging the low cost of FPD (flat panel display) manufacturing. In some embodiments, the ROIC is specifically designed for sensing a specific electromagnetic wavelength (such as X-Rays, THz, LWIR).

FIG. 12 illustrates an exemplary sensor. In some embodiments, sensor 1200 is manufactured using method 1100. Sensor 1200 includes glass substrate 1206, structure 1204 less than 250 nm wide coupled to glass substrate 1206, and a sensor pixel 1202 coupled to the structure 1204. In some embodiments of sensor 1200, structure 1204 is a hinge that thermally separates the active area from the glass. In some embodiments, sensor 1200 receives an input current or charge and outputs an output current or charge based on the received radiation (e.g., the resistance between two terminals of the sensor changes in response to exposure to LWIR radiation).

In some embodiments, a sensor includes a glass substrate, a structure manufactured from any of the methods described herein and coupled to the glass substrate, and a sensor pixel coupled to the structure.

In some embodiments, a sensor includes a MEMS or NEMS device manufactured by a LCD-TFT manufacturing process and a structure manufactured by any of the methods described herein.

By way of examples, sensors can include resistive sensors and capacitive sensors. Bolometers can be used in a variety of applications. For example, long wave infra-red (LWIR, wavelength of approximately 8-14 μm) bolometers can be used in the automotive and commercial security industries. For example, LWIR bolometers with QVGA, VGA, and other resolution. Terahertz (THz, wavelength of approximately 1.0-0.1 mm) bolometers can be used in security (e.g., airport passenger security screening) and medical (medical imaging). For example, THz bolometers with QVGA resolution and other resolutions. Some electromechanical systems can include X-Ray sensors or camera systems. Similarly, LWIR and THz sensors are used in camera systems. Some electromechanical systems are applied in medical imaging, such as endoscopes and exoscopes. X-ray sensors include direct and indirect sensing configurations.

Other electromechanical systems include scanners for light detection and ranging (LIDAR) systems. For example, optical scanners where spatial properties of a laser beam could be shaped (for, e.g., beam pointing). Electromechanical systems include inertial sensors (e.g., where the input stimulus is linear or angular motion). Some systems may be used in bio sensing and bio therapeutic platforms (e.g., where biochemical agents are detected).

In some embodiments, a non-transitory computer readable storage medium stores one or more programs, and the one or more programs includes instructions. When the instructions are executed by an electronic device (e.g., circuit 100, circuit 200, circuit 300, circuit 400, circuit 500, circuit 600, circuit 700, circuit 800, circuit 850) with one or more processors and memory, the instructions cause the electronic device to perform the methods described with respect to FIGS. 1-10.

In some embodiments, a circuit, comprises: a first TFT configured to output a current to a power consuming device; a second TFT configured to couple a control voltage to the first TFT, the control voltage controlling an amount of the current; and a storage capacitor coupled to the first and second TFTs, the storage capacitor configured to store the control voltage.

In some embodiments, the power consuming device comprises an infrared emitting device.

In some embodiments, the power consuming device comprises an electrochemical bath.

In some embodiments, the circuit further comprises a source follower. The source follower comprises the first TFT.

In some embodiments, the circuit further comprises a third TFT configured to output the current to the power consuming device. The second TFT is configured to couple the control voltage to the third TFT.

In some embodiments, the circuit further comprises a third TFT configured to couple the power consuming device to a ground voltage.

In some embodiments, the circuit further comprises: a third TFT configured to output a second current to a second power consuming device; a fourth TFT configured to couple a second control voltage to the third TFT, the second control voltage controlling an amount of the second current; and a second storage capacitor coupled to the third and fourth TFTs for storing the second control voltage. In response to receiving a row control signal: the second TFT couples the first control voltage to the first TFT, and the fourth TFT couples the second control voltage to the third TFT.

In some embodiments, the circuit further comprises: a third TFT configured to output a second current to a second power consuming device; a fourth TFT configured to couple the control voltage to the third TFT, the control voltage controlling an amount of the second current; and a second storage capacitor coupled to the third and fourth TFTs for storing the second control voltage.

In some embodiments, the second TFT is configured for sensing a voltage of the power consuming device.

In some embodiments, the amount of current is 1-50 μA.

In some embodiments, the circuit further comprises a glass substrate. The first and second TFTs are disposed on the glass substrate.

In some embodiments, the circuit further comprises a ring and a mesh coupled to a power supply or a ground voltage for providing the current. The mesh has a pitch of 10-200 μm.

In some embodiments, the power consuming device is coupled between the first TFT and ground.

In some embodiments, the power consuming device is coupled between a power supply for providing the current and the first TFT.

In some embodiments, a method for operating a circuit comprising a first TFT, a second TFT, and a storage capacitor, comprises: coupling, via the second TFT, a control voltage to the first TFT; in response to coupling to the control voltage, outputting, via the first TFT, a current to a power consuming device, wherein the control voltage controls an amount of the current; and storing, via the storage capacitor, the control voltage.

In some embodiments, the power consuming device comprises an infrared emitting device, and the infrared emitting device is configured to emit infrared radiation in response to receiving the current.

In some embodiments, the power consuming device comprises an electrochemical bath, and the current is provided to the electrochemical bath for electroplating.

In some embodiments, the method further comprises coupling, via a third TFT, the power consuming device to a ground voltage.

In some embodiments, the method further comprises sensing a voltage of the power consuming device.

In some embodiments, a method for fabricating a circuit comprises: providing a power consuming device; providing a first TFT and coupling the first TFT to the power consuming device. The first TFT is configured to output a current to the power consuming device. The method further comprises providing a second TFT and coupling the second TFT to the first TFT. The second TFT is configured to couple a control voltage to the first TFT, the control voltage controlling an amount of the current. The method further comprises providing a storage capacitor, wherein the storage capacitor is configured to store the control voltage; and coupling the storage capacitor to the first and second TFTs.

Although “electrically coupled” and “coupled” are used to describe the electrical connections between two electronic components or elements in this disclosure, it is understood that the electrical connections do not necessarily need direct connection between the terminals of the components or elements being coupled together. For example, electrical routing connects between the terminals of the components or elements being electrically coupled together. In another example, a closed (conducting or an “on”) switch is connected between the terminals of the components being coupled together. In yet another example, additional elements connect between the terminals of the components being coupled together without affecting the characteristics of the circuit. For example, buffers, amplifiers, and passive circuit elements can be added between components or elements being coupled together without affecting the characteristics of the disclosed circuits and departing from the scope of this disclosure.

Those skilled in the art will recognize that the systems described herein are representative, and deviations from the explicilty disclosed embodiments are within the scope of the disclosure. For example, some embodiments include additional sensors or cameras, such as cameras covering other parts of the electromagnetic spectrum, can be devised using the same principles.

Although the disclosed embodiments have been fully described with reference to the accompanying drawings, it is to be noted that various changes and modifications will become apparent to those skilled in the art. Such changes and modifications are to be understood as being included within the scope of the disclosed embodiments as defined by the appended claims.

The terminology used in the description of the various described embodiments herein is for the purpose of describing particular embodiments only and is not intended to be limiting. As used in the description of the various described embodiments and the appended claims, the singular forms “a”, “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

We claim:

1. A circuit, comprising:
a first thin-film transistor (TFT) configured to output a current to a power consuming device;
a second TFT configured to couple a control voltage to the first TFT, the control voltage controlling an amount of the current; and
a storage capacitor coupled to the first and second TFTs, the storage capacitor configured to store the control voltage.

2. The circuit of claim 1, wherein the power consuming device comprises an infrared emitting device.

3. The circuit of claim 1, further comprising a source follower, wherein the source follower comprises the first TFT.

4. The circuit of claim 1, further comprising a third TFT configured to output the current to the power consuming device, wherein the second TFT is configured to couple the control voltage to the third TFT.

5. The circuit of claim 1, further comprising a third TFT configured to couple the power consuming device to a ground voltage.

6. The circuit of claim 1, further comprising:
a third TFT configured to output a second current to a second power consuming device;
a fourth TFT configured to couple a second control voltage to the third TFT, the second control voltage controlling an amount of the second current; and
a second storage capacitor coupled to the third and fourth TFTs for storing the second control voltage,
wherein in response to receiving a row control signal:
the second TFT couples the first control voltage to the first TFT, and
the fourth TFT couples the second control voltage to the third TFT.

7. The circuit of claim 1, further comprising:
a third TFT configured to output a second current to a second power consuming device;
a fourth TFT configured to couple the control voltage to the third TFT, the control voltage controlling an amount of the second current; and
a second storage capacitor coupled to the third and fourth TFTs for storing the second control voltage.

8. The circuit of claim 1, wherein the second TFT is configured for sensing a voltage of the power consuming device.

9. The circuit of claim 1, wherein the amount of current is 1-50 μA.

10. The circuit of claim 1, further comprising a glass substrate, wherein the first and second TFTs are disposed on the glass substrate.

11. The circuit of claim 1, further comprising a ring and a mesh coupled to a power supply or a ground voltage for providing the current, wherein the mesh has a pitch of 10-200 μm.

12. The circuit of claim 1, wherein the power consuming device is coupled between the first TFT and ground.

13. The circuit of claim 1, wherein the power consuming device is coupled between a power supply for providing the current and the first TFT.

14. A method for operating a circuit comprising a first TFT, a second TFT, and a storage capacitor, comprising:
coupling, via the second TFT, a control voltage to the first TFT;
in response to coupling to the control voltage, outputting, via the first TFT, a current to a power consuming device, wherein the control voltage controls an amount of the current; and
storing, via the storage capacitor, the control voltage.

15. The method of claim 14, wherein:
the power consuming device comprises an infrared emitting device, and
the infrared emitting device is configured to emit infrared radiation in response to receiving the current.

16. The method of claim 14, further comprising coupling, via a third TFT, the power consuming device to a ground voltage.

17. The method of claim 14, further comprising sensing a voltage of the power consuming device.

18. A method for fabricating a circuit comprising:
providing a power consuming device;
providing a first TFT;
coupling the first TFT to the power consuming device, wherein the first TFT is configured to output a current to the power consuming device;
providing a second TFT;
coupling the second TFT to the first TFT, wherein the second TFT is configured to couple a control voltage to the first TFT, the control voltage controlling an amount of the current;
providing a storage capacitor, wherein the storage capacitor is configured to store the control voltage; and
coupling the storage capacitor to the first and second TFTs.
